(19) United States
(12) Patent Application Publication
(10) Pub. No.: US 2025/0227935 A1
(43) Pub. Date: Jul. 10, 2025

(54) SEMICONDUCTOR STRUCTURE AND MANUFACTURING METHOD THEREOF

(71) Applicant: MACRONIX INTERNATIONAL CO., LTD., Hsinchu (TW)

(72) Inventors: Dai-Ying LEE, Hsinchu County (TW); Ming-Hsiu LEE, Hsinchu City (TW); Zefu ZHAO, Taipei City (TW); Wei-Teng HSU, New Taipei City (TW); Chee-Wee LIU, Taipei City (TW)

(21) Appl. No.: 18/679,744

(22) Filed: May 31, 2024

Related U.S. Application Data
(60) Provisional application No. 63/619,317, filed on Jan. 10, 2024.

(51) Int. Cl. H10B 51/30; H10B 51/20

(52) U.S. Cl. CPC H10B 51/30; H10B 51/20

(57) ABSTRACT

The present disclosure provides a semiconductor structure and a manufacturing method thereof. The semiconductor structure includes a semiconductor substrate, an underlayer, a ferroelectric material layer, and a conductive layer. The underlayer covers the semiconductor substrate. The ferroelectric material layer covers the underlayer, in which the underlayer has a surface facing the ferroelectric material layer, and the surface has a root mean square roughness of less than 1 nm. The conductive layer covers the ferroelectric material layer.

### CROSS-REFERENCE TO RELATED APPLICATION

This application claims priority to U.S. Provisional Application Ser. No. 63/619,317, filed Jan. 10, 2024, which is herein incorporated by reference.

### BACKGROUND

### Field of Invention

The present disclosure relates to a semiconductor structure and a manufacturing method thereof.

### Description of Related Art

As time progresses, mobile electronic products have become increasingly important, resulting in an increasing demand for non-volatile memories. Common non-volatile memories include mask read-only memory (Mask ROM), flash memory, and so on. However, the mask read-only memory cannot change the contents of the memory, so its applicability is greatly limited. Although the flash memory can change the contents of the memory at will, its number of writes is limited, and its read and write speeds are much lower than that of dynamic random-access memory (DRAM) and static random-access memory (SRAM). Therefore, the demand for a new memory with high read and write times, high read and write speeds, low energy consumption, and low operating voltage has gradually emerged. Currently, a new memory with these advantages is a ferroelectric random access memory (FeRAM). There is an urgent need to further improve the performance of the FeRAM and expand its application.

### SUMMARY

The present disclosure provides a semiconductor structure that includes a semiconductor substrate, an underlayer, a ferroelectric material layer, and a conductive layer. The underlayer covers the semiconductor substrate. The ferroelectric material layer covers the underlayer, in which the underlayer has a surface facing the ferroelectric material layer, and the surface has a root mean square (RMS) roughness of less than 1 nm. The conductive layer covers the ferroelectric material layer.

In some embodiments, the semiconductor structure further includes an insulating layer disposed between the underlayer and the ferroelectric material layer.

In some embodiments, the semiconductor structure further includes an insulating layer disposed between the ferroelectric material layer and the conductive layer.

In some embodiments, the semiconductor structure further includes a first insulating layer and a second insulating layer, in which the first insulating layer is disposed between the underlayer and the ferroelectric material layer, and the second insulating layer is disposed between the ferroelectric material layer and the conductive layer.

In some embodiments, the semiconductor substrate is columnar, the underlayer surrounds the semiconductor substrate, the ferroelectric material layer surrounds the underlayer, and the conductive layer surrounds the ferroelectric material layer.

In some embodiments, the semiconductor structure further includes an insulating layer disposed between the underlayer and the ferroelectric material layer.

In some embodiments, the semiconductor structure further includes an insulating layer disposed between the ferroelectric material layer and the conductive layer.

In some embodiments, the semiconductor structure further includes a first insulating layer and a second insulating layer, in which the first insulating layer is disposed between the underlayer and the ferroelectric material layer, and the second insulating layer is disposed between the ferroelectric material layer and the conductive layer.

In some embodiments, the underlayer has a thickness of 0.5 nm to 50 nm.

In some embodiments, the underlayer includes titanium (Ti), titanium nitride (TiN), titanium aluminum alloy (TiAl alloy), titanium aluminum nitride (TiAlN), tungsten (W), tungsten nitride (WN), tantalum (Ta), tantalum nitride (TaN), ruthenium (Ru), ruthenium dioxide (RuO₂), molybdenum (Mo), molybdenum dioxide (MoO₂), molybdenum trioxide (MoO₃), silicon (Si), germanium (Ge), silicon germanium, or combinations thereof.

The present disclosure provides a method of manufacturing a semiconductor structure, and it includes the following operations. An underlayer is formed to cover a semiconductor substrate. A surface of the underlayer is treated to lower a roughness of the surface. A ferroelectric material layer is formed to cover the surface of the underlayer. A conductive layer is formed to cover the ferroelectric material layer.

In some embodiments, treating the surface of the underlayer to lower the roughness of the surface includes planarizing the surface by a chemical mechanical polishing (CMP) process.

In some embodiments, a polishing slurry of the chemical mechanical polishing process includes water.

In some embodiments, the method further includes: forming an insulating layer to cover the surface of the underlayer before forming the ferroelectric material layer to cover the surface of the underlayer.

In some embodiments, the method further includes: forming an insulating layer to cover the ferroelectric material layer before forming the conductive layer to cover the ferroelectric material layer.

In some embodiments, the method further includes: before forming the ferroelectric material layer to cover the surface of the underlayer, forming a first insulating layer to cover the surface of the underlayer; and before forming the conductive layer to cover the ferroelectric material layer, forming a second insulating layer to cover the ferroelectric material layer.

In some embodiments, the semiconductor substrate is columnar, and forming the underlayer to cover the semiconductor substrate includes: forming the underlayer to surround a sidewall of the semiconductor substrate.

In some embodiments, the method further includes: forming an insulating layer to cover the surface of the underlayer before forming the ferroelectric material layer to cover the surface of the underlayer.

In some embodiments, the method further includes: forming an insulating layer to cover the ferroelectric material layer before forming the conductive layer to cover the ferroelectric material layer.

In some embodiments, after treating the surface of the underlayer to lower the roughness of the surface, the surface has a root mean square roughness of less than 1 nm.

### BRIEF DESCRIPTION OF THE DRAWINGS

The present disclosure can be more fully understood by reading the following detailed description of the embodiments, with reference made to the accompanying drawings.

FIG. 1 is a flow diagram of a manufacturing method of a semiconductor structure according to various embodiments of the present disclosure.

FIG. 2 to FIG. 4 are schematic cross-sectional views of intermediate stages of manufacturing a semiconductor structure according to various embodiments of the present disclosure.

FIG. 5 shows oxygen vacancy distribution and dipole distribution in a semiconductor structure according to various embodiments of the present disclosure.

FIG. 6 shows oxygen vacancy distribution and dipole distribution in a semiconductor structure according to a comparative example of the present disclosure.

FIG. 7 to FIG. 9 are schematic cross-sectional views of semiconductor structures according to various embodiments of the present disclosure.

FIG. 10 to FIG. 13 are three-dimensional schematic diagrams of semiconductor structures according to various embodiments of the present disclosure.

FIG. 14 is a transmission electron microscope (TEM) image of a semiconductor structure of Comparative Example 1 according to the present disclosure.

FIG. 15 is a TEM image of a semiconductor structure according to Example 1 of the present disclosure.

FIG. 16 is a Weibull plot of the breakdown voltages of Example 1 and Comparative Example 1 of the present disclosure.

FIG. 17 is a remnant polarization-read number relationship diagram of Example 1 and Comparative Example 1 of the present disclosure.

### DETAILED DESCRIPTION

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

The present disclosure provides a semiconductor structure and a manufacturing method thereof. The semiconductor structure includes a semiconductor substrate, an underlayer, a ferroelectric material layer, and a conductive layer, in which the semiconductor substrate is covered by the underlayer, the ferroelectric material layer, and the conductive layer in sequence. In the manufacturing method, before the ferroelectric material layer is formed to cover the surface of the underlayer, the surface of the underlayer is treated to reduce the surface roughness to a sub-nanometer level roughness, so that the ferroelectric material layer covering the underlayer can have good uniformity, good flatness, good crystallinity, and less oxygen vacancies. Therefore, the semiconductor structure of the present disclosure can have good electrical performance and reliability, such as high remnant polarization (2Pᵣ), high breakdown voltage, and high endurance. The high uniformity is particularly important for the performance of integrated circuit components. The semiconductor structure of the present disclosure can be applied to a ferroelectric random access memory (FeRAM), a ferroelectric field effect transistor (FeFET), or a ferroelectric tunnel junction (FTJ) device. The FeFET is, for example, a planar transistor. More specifically, the FeRAM, FeFET, or FTJ device may include the semiconductor structure of the present disclosure.

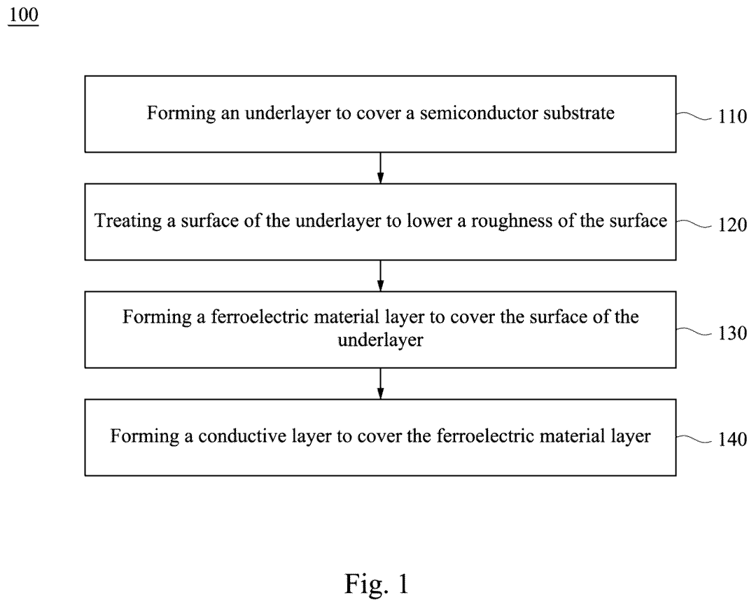

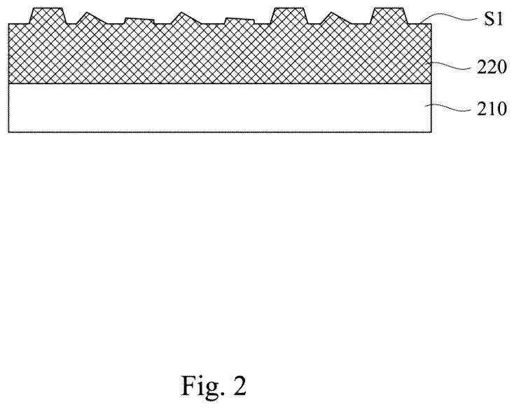

Please refer to FIG. 1 and FIG. 2 to FIG. 4. FIG. 1 is a flow diagram of a manufacturing method 100 of a semiconductor structure according to various embodiments of the present disclosure. The manufacturing method 100 includes operation 110, operation 120, operation 130, and operation 140. FIG. 2 to FIG. 4 are schematic cross-sectional views of intermediate stages of manufacturing a semiconductor structure according to various embodiments of the present disclosure. Although a series of operations or steps are used below to describe the method disclosed herein, an order of these operations or steps should not be construed as a limitation to the present disclosure. For example, some operations or steps may be performed in a different order, and/or other steps may be performed at the same time. In addition, it is not necessary to perform all of the operations, steps, and/or features shown to achieve the embodiments of the present disclosure. In addition, each operation or step described herein may contain several sub-steps or actions.

In operation 110, as shown in FIG. 2, an underlayer 220 is formed to cover a semiconductor substrate 210. The surface S1 of the underlayer 220 has a root mean square roughness, and the root mean square roughness is, for example, greater than 1.5, 2, 3, 4, 5, 6, 7, or 8 nm. In the present disclosure, the “root mean square roughness” is measured by an atomic force microscope (AFM). In some embodiments, a method of forming the underlayer 220 includes sputtering, chemical vapor deposition (CVD), or atomic layer deposition (ALD).

In some embodiments, the semiconductor substrate 210 includes silicon, germanium, silicon germanium, a silicon on insulator (SOI), a germanium on insulator (GOI), a silicon germanium on insulator (SiGOI), glass, or combinations thereof. In some embodiments, the underlayer 220 includes a pure metal, an alloy, a conductive metal oxide, a conductive metal nitride, conductive silicon, or combinations thereof. In some embodiments, the underlayer 220 includes titanium, titanium nitride, titanium aluminum alloy, titanium aluminum nitride, tungsten, tungsten nitride, tantalum, tantalum nitride, ruthenium, ruthenium dioxide, molybdenum, molybdenum dioxide, molybdenum trioxide, silicon, germanium, silicon germanium, or combinations thereof. The silicon can be undoped silicon or doped silicon. In some embodiments, the underlayer 220 is a titanium nitride layer. In some embodiments, the underlayer 220 is an amorphous titanium nitride layer.

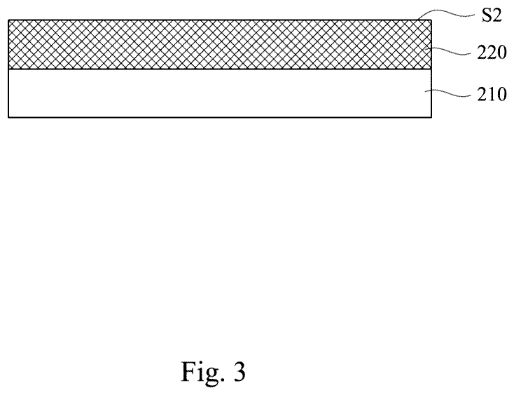

In operation 120, as shown in FIG. 2 and FIG. 3, the surface S1 of the underlayer 220 is treated to lower the roughness of the surface S1 to form the surface S2 shown in FIG. 3. In other words, in operation 120, the surface S1 of underlayer 220 is planarized. In some embodiments, after treating the surface S1 of the underlayer 220 to lower the roughness of the surface S1, the surface S2 has a root mean square roughness of less than 1 nm. The root mean square roughness is, for example, less than 1, 0.9, 0.8, 0.7, 0.6, 0.5, 0.4, or 0.3 nm. In some embodiments, treating the surface S1 of the underlayer 220 to lower the roughness of the surface S1 includes planarizing the surface S1 by a chemical mechanical polishing process. In some embodiments, a polishing slurry of the chemical mechanical polishing process includes water. In some embodiments, the polishing slurry is water and is free of other components. Therefore, the operation of the treating the underlayer 220 of the present disclosure may have the advantages of simple operation and low cost. In other embodiments, the roughness of the surface S1 can be lowered through other polishing processes. In some embodiments, the underlayer 220 shown in FIG. 3 has a thickness of 0.5 nm to 50 nm, such as 0.5, 1, 5, 10, 15, 20, 25, 30, 35, 40, 45, or 50 nm. If the thickness is greater than 50 nm, subsequent processes may be difficult to carry out. In some embodiments, the underlayer 220 having the surface S2, which is substantially planar, is an amorphous titanium nitride layer. Compared with a crystallized titanium nitride layer, the amorphous titanium nitride layer is more conducive to the subsequent formation of a ferroelectric material layer with c-axes of orthorhombic phase (o-phase) well-aligned along the deposition direction.

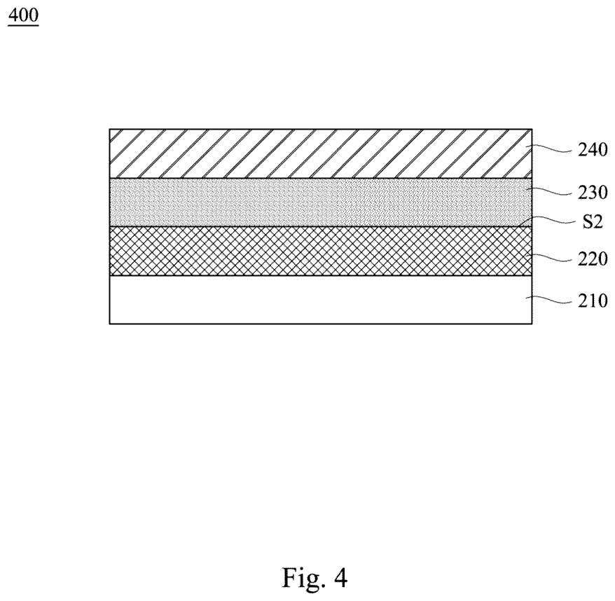

In operation 130, as shown in FIG. 4, a ferroelectric material layer 230 is formed to cover the surface S2 of the underlayer 220. In some embodiments, a method of forming the ferroelectric material layer 230 includes plasma-assisted atomic layer deposition, metal-organic chemical vapor deposition, chemical vapor deposition, physical vapor deposition, sputtering, or pulsed laser deposition. In some embodiments, the ferroelectric material layer 230 includes hafnium zirconium oxide (HfZrO₂, HZO), hafnium zirconium oxynitride (HfZrON), hafnium zirconium aluminum oxide (HfZrAlO), or hafnium oxide (HfO₂) containing a dopant, in which the dopant includes zirconium (Zr), silicon (Si), strontium (Sr), yttrium (Y), lanthanum (La), germanium (Ge), aluminum (Al), or gadolinium (Gd). The hafnium zirconium oxide may be hafnium dioxide-zirconium dioxide (HfO₂-ZrO₂) with a superlattice structure. In some embodiments, in the hafnium dioxide-zirconium dioxide having the superlattice structure, both the uppermost and the lowermost layers are zirconium dioxide layers. In some embodiments, the ferroelectric material layer 230 has a thickness of 5 nm to 30 nm, such as 5, 10, 15, 20, 25, or 30 nm. If the thickness is greater than 30 nm, it may be detrimental to subsequent processes; if the thickness is less than 5 nm, the ferroelectric material layer 230 may not have the ferroelectric properties required for the semiconductor structure. In addition, when the thickness of the underlayer 220 is smaller, it is beneficial to improve the remnant polarization properties of the ferroelectric material layer 230.

In operation 140, as shown in FIG. 4, a conductive layer 240 is formed to cover the ferroelectric material layer 230. A semiconductor structure 400 includes the semiconductor substrate 210, the underlayer 220, the ferroelectric material layer 230, and the conductive layer 240. The underlayer 220 covers the semiconductor substrate 210. The ferroelectric material layer 230 covers the underlayer 220, in which the underlayer 220 has the surface S2 facing the ferroelectric material layer 230, and the surface S2 has the root mean square roughness of less than 1 nm. The conductive layer 240 covers the ferroelectric material layer 230. In some embodiments, the conductive layer 240 includes a pure metal, an alloy, a conductive metal oxide, a conductive metal nitride, conductive silicon, or combinations thereof. In some embodiments, the conductive layer 240 is a single layer or a stack of multiple layers. In some embodiments, the conductive layer 240 includes titanium, titanium nitride, titanium aluminum alloy, titanium aluminum nitride, tungsten, tungsten nitride, tantalum, tantalum nitride, ruthenium, ruthenium dioxide, molybdenum, molybdenum dioxide, molybdenum trioxide, polycrystalline silicon, platinum, or combinations thereof. In some embodiments, the semiconductor structure 400 is a metal/ferroelectric layer/metal (MFM) structure.

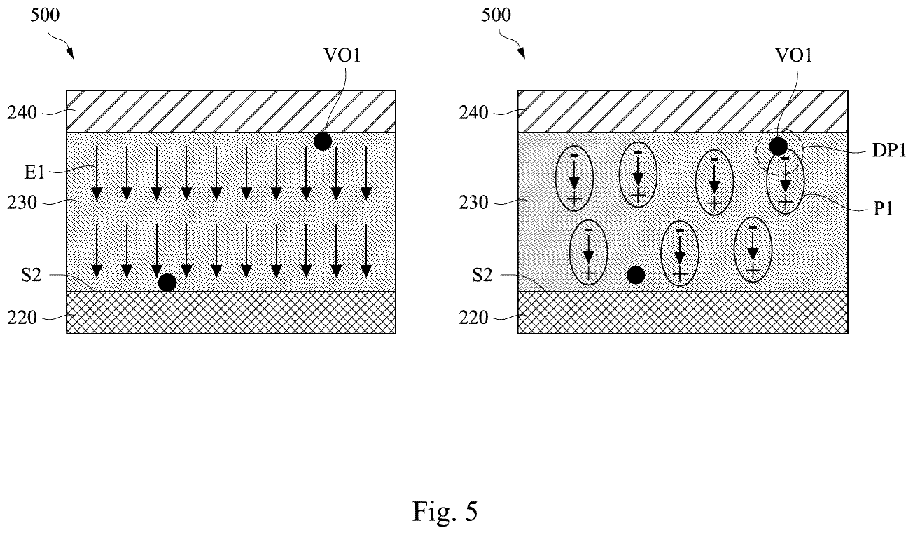

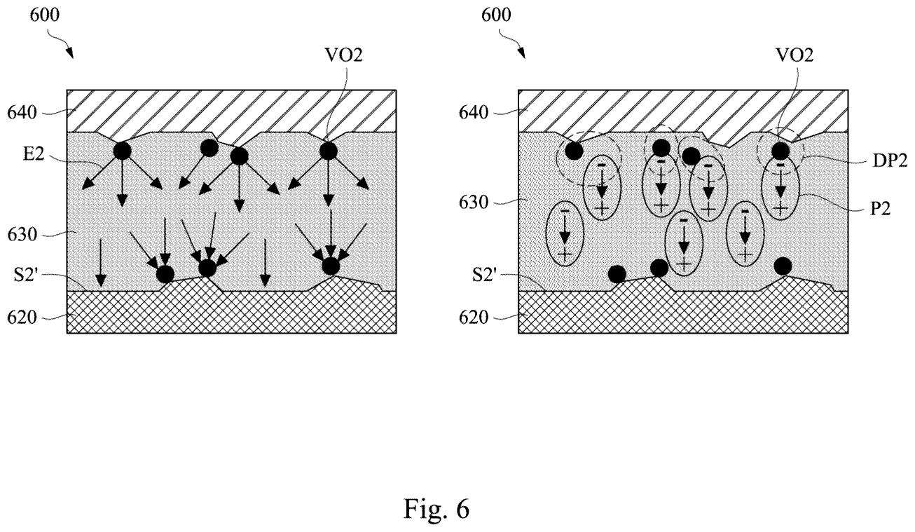

Next, the advantages of operation 120 of FIG. 1 are illustrated with FIG. 5 and FIG. 6. FIG. 5 shows oxygen vacancy distribution and dipole distribution in a semiconductor structure 500 according to various embodiments of the present disclosure. FIG. 6 shows oxygen vacancy distribution and dipole distribution in a semiconductor structure 600 according to a comparative example of the present disclosure. The oxygen vacancy (Vₒ²⁺) is a vacancy left after a material loses oxygen, so it has 2 positive charges.

As shown in FIG. 5, the semiconductor structure 500 includes the underlayer 220, the ferroelectric material layer 230, and the conductive layer 240, in which the ferroelectric material layer 230 covers the underlayer 220, and the conductive layer 240 covers the ferroelectric material layer 230. The underlayer 220, the ferroelectric material layer 230, and the conductive layer 240 can be a TiN layer, a HZO layer, and a TiN layer respectively. The surface S2 of the underlayer 220 is planarized by the CMP process, so the upper and lower surfaces of the ferroelectric material layer 230 formed on the underlayer 220 are flat, and the ferroelectric material layer 230 has good uniformity. By applying a bias voltage to the ferroelectric material layer 230 to form an electric field E1 in the ferroelectric material layer 230, the direction of dipoles P1 in the ferroelectric material layer 230 can be controlled. Since the electric field E1 is uniform, only a small amount of oxygen vacancies VO1 is generated in the ferroelectric material layer 230. A dipole pinning DP1 may be formed between one oxygen vacancy VO1 and one dipole P1, thereby limiting the rotation of the dipole P1.

As shown in FIG. 6, the semiconductor structure 600 includes an underlayer 620, a ferroelectric material layer 630, and a conductive layer 640, in which the ferroelectric material layer 630 covers the underlayer 620, and the conductive layer 640 covers the ferroelectric material layer 630. The underlayer 620, the ferroelectric material layer 630, and the conductive layer 640 can be a TiN layer, a HZO layer, and a TiN layer respectively. The surface S2′ of the underlayer 620 is not planarized by the CMP process, so the upper and lower surfaces of the ferroelectric material layer 630 formed on the underlayer 620 are rough and uneven. By applying a bias voltage to the ferroelectric material layer 630 to form an electric field E2 in the ferroelectric material layer 630, the direction of the dipoles P2 in the ferroelectric material layer 630 can be controlled. The rough and uneven surfaces of the ferroelectric material layer 630 may enhance the surface electric field, causing a larger number of oxygen vacancies VO2 to be generated in the ferroelectric material layer 630. A dipole pinning DP2 may be formed between one oxygen vacancy VO2 and one dipole P2, thereby limiting the rotation of the dipole P2.

Please refer to FIG. 5 and FIG. 6 at the same time. The distribution of the electric field E1 of the ferroelectric material layer 230 in FIG. 5 is more uniform than the distribution of the electric field E2 of the ferroelectric material layer 630 of FIG. 6. Therefore, the oxygen vacancies VO1 of the ferroelectric material layer 230 of FIG. 5 are less than the oxygen vacancies VO2 of the ferroelectric material layer 630 of FIG. 6. Therefore, the dipole pinning effect in the ferroelectric material layer 630 of FIG. 6 is more severe. The ferroelectric material layer 630 may suffer from remnant polarization fatigue (2Pᵣ fatigue). Therefore, compared with the ferroelectric material layer 630, the ferroelectric material layer 230 formed on the underlayer 220, which is planarized, can have higher remnant polarization and breakdown voltage. In addition, since the underlayer 220 has the substantially flat surface S2, c-axes of orthorhombic phase in the ferroelectric material layer 230 are well-aligned along the deposition direction.

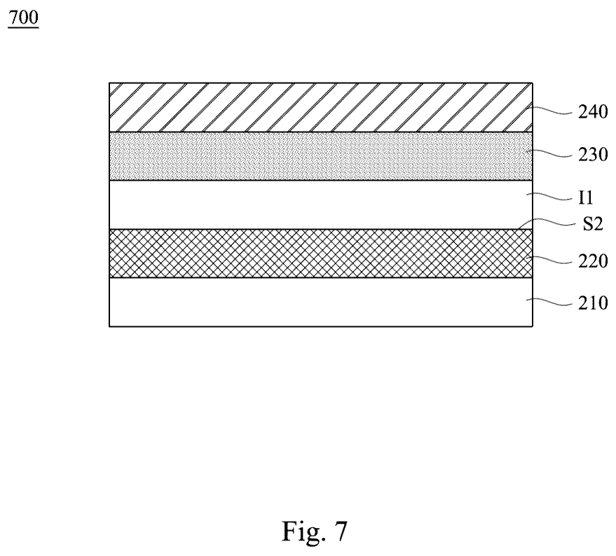

FIG. 7 to FIG. 9 are schematic cross-sectional views of semiconductor structures according to various embodiments of the present disclosure.

As shown in FIG. 7, a semiconductor structure 700 further includes an insulating layer I1 disposed between the underlayer 220 and the ferroelectric material layer 230. The semiconductor structure 700 may be manufactured with reference to the manufacturing method 100 of FIG. 1. Compared with the manufacturing method 100, the manufacturing method of the semiconductor structure 700 further includes forming the insulating layer I1 to cover the surface S2 of the underlayer 220 before forming the ferroelectric material layer 230 to cover the surface S2 of the underlayer 220. The insulating layer I1 can reduce leakage current. Since the underlayer 220 has the substantially flat surface S2, the insulating layer I1 and the ferroelectric material layer 230 can both have good uniformity and flatness, and the ferroelectric material layer 230 can have good crystallinity and less oxygen vacancies. In some embodiments, the insulating layer I1 includes aluminum oxide (Al₂O₃), hafnium dioxide (HfO₂), zirconium dioxide (ZrO₂), titanium dioxide (TiO₂), tantalum pentoxide (Ta₂O₅), yttrium oxide (Y₂O₃), silicon dioxide (SiO₂), silicon carbonitride (SiCN), silicon nitride (Si₃N₄), silicon oxynitride, or combinations thereof. In some embodiments, the thickness of the insulating layer I1 is 0.1 nm to 20 nm, such as 0.1, 0.5, 1, 2, 4, 6, 8, 10, 12, 14, 16, 18, or 20 nm. In some embodiments, the semiconductor structure 700 is a metal/ferroelectric layer/insulator/metal (MFIM) structure.

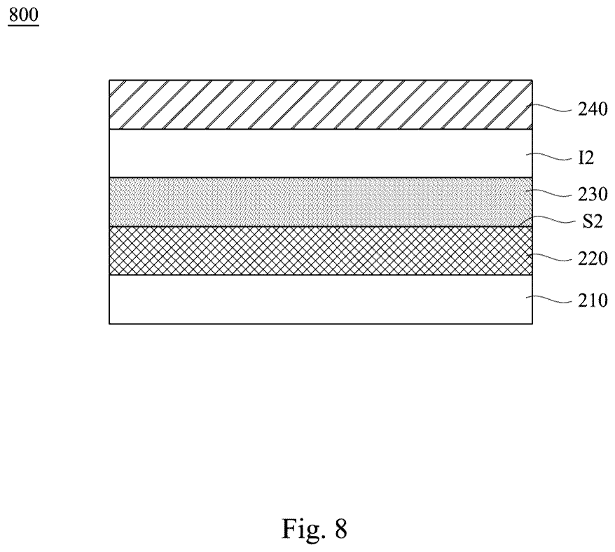

As shown in FIG. 8, the semiconductor structure 800 further includes an insulating layer I2 disposed between the ferroelectric material layer 230 and the conductive layer 240. The semiconductor structure 800 can be manufactured with reference to the manufacturing method 100 of FIG. 1. Compared with the manufacturing method 100, the manufacturing method of the semiconductor structure 800 further includes forming the insulating layer I2 to cover the ferroelectric material layer 230 before forming the conductive layer 240 to cover the ferroelectric material layer 230. The insulating layer I2 can reduce leakage current. In some embodiments, the insulating layer I2 includes aluminum oxide, hafnium dioxide, zirconium dioxide, titanium dioxide, tantalum pentoxide, yttrium oxide, silicon dioxide, silicon carbonitride, silicon nitride, silicon oxynitride, or combinations thereof. In some embodiments, the thickness of the insulating layer I2 is 0.1 nm to 20 nm, such as 0.1, 0.5, 1, 2, 4, 6, 8, 10, 12, 14, 16, 18, or 20 nm. In some embodiments, the semiconductor structure 800 is a metal/insulator/ferroelectric layer/metal (MIFM) structure.

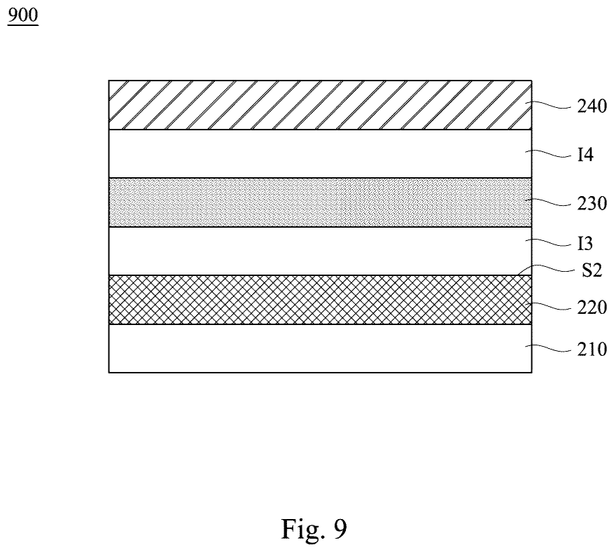

As shown in FIG. 9, the semiconductor structure 900 further includes a first insulating layer I3 and a second insulating layer I4. The first insulating layer I3 is disposed between the underlayer 220 and the ferroelectric material layer 230. The second insulating layer I4 is disposed between the ferroelectric material layer 230 and the conductive layer 240. The first insulating layer I3 and the second insulating layer I4 can reduce leakage current. Since the underlayer 220 has the substantially flat surface S2, both the first insulating layer I3 and the ferroelectric material layer 230 can have good uniformity and flatness, and the ferroelectric material layer 230 can have good crystallinity and less oxygen vacancies. The semiconductor structure 900 can be manufactured with reference to the manufacturing method 100 of FIG. 1. Compared with the manufacturing method 100, the manufacturing method of the semiconductor structure 900 further includes forming the first insulating layer I3 to cover the surface S2 of the underlayer 220 before forming the ferroelectric material layer 230 to cover the surface S2 of the underlayer 220; and forming the second insulating layer I4 to cover the ferroelectric material layer 230 before forming the conductive layer 240 to cover the ferroelectric material layer 230. In some embodiments, the semiconductor structure 900 is a metal/insulator/ferroelectric layer/insulator/metal (MIFIM) structure. In some embodiments, the first insulating layer I3 or the second insulating layer I4 may include the material of the insulating layer I1 or the insulating layer I2 mentioned previously, so details will not be described again.

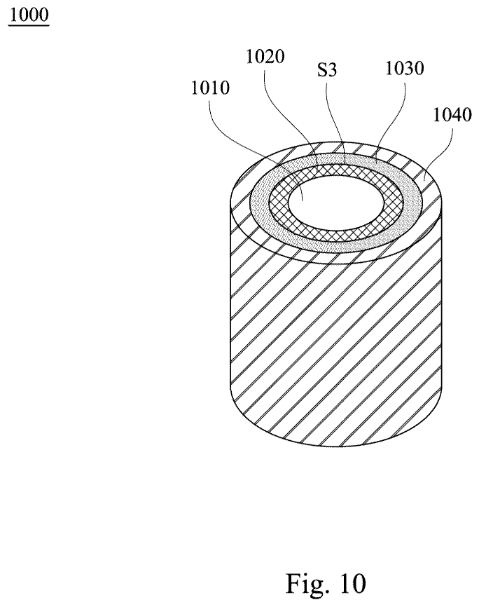

FIG. 10 to FIG. 13 are three-dimensional schematic diagrams of semiconductor structures according to various embodiments of the present disclosure.

As shown in FIG. 10, a semiconductor substrate 1010 is columnar, a underlayer 1020 surrounds the semiconductor substrate 1010, a ferroelectric material layer 1030 surrounds the underlayer 1020, and a conductive layer 1040 surrounds the ferroelectric material layer 1030. The underlayer 1020 has a surface S3 facing the ferroelectric material layer 1030, and the surface S3 has a root mean square roughness of less than 1 nm. The root mean square roughness is, for example, less than 1, 0.9, 0.8, 0.7, 0.6, 0.5, 0.4, or 0.3 nm. The semiconductor structure 1000 can be manufactured with reference to the manufacturing method 100 of FIG. 1. The method of manufacturing the semiconductor structure 1000 includes the following operations: forming the underlayer 1020 to cover the semiconductor substrate 1010. More specifically, The underlayer 1020 is formed to surround the sidewall of the semiconductor substrate 1010. The surface S3 of the underlayer 1020 is treated to reduce the roughness of the surface S3. For example, the roughness of the surface S3 can be reduced through a polishing process. The ferroelectric material layer 1030 is formed to cover the surface S3 (i.e., sidewall) of the underlayer 1020. The conductive layer 1040 is formed to cover the sidewall of the ferroelectric material layer 1030. In some embodiments, the semiconductor structure 1000 is a MFM structure.

Please continue to refer to FIG. 10. Since the surface S3 of the underlayer 1020 has smaller roughness, the ferroelectric material layer 1030 can have good uniformity, good flatness, good crystallinity, and less oxygen vacancies, so that the semiconductor structure 1000 has good electrical performance and reliability.

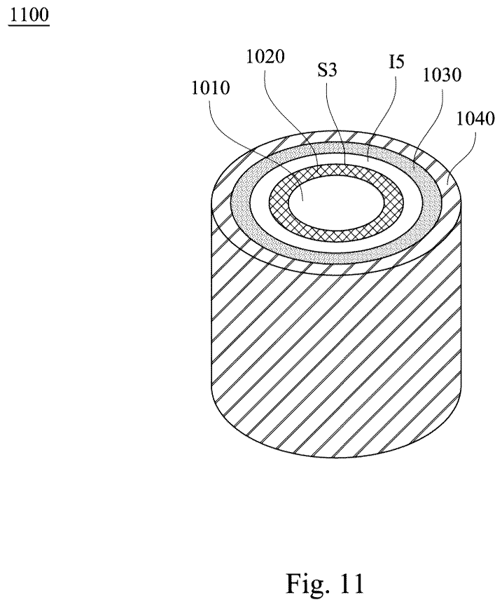

As shown in FIG. 11, a semiconductor structure 1100 further includes an insulating layer I5 disposed between the underlayer 1020 and the ferroelectric material layer 1030. The semiconductor structure 1100 may be manufactured with reference to the method of manufacturing the semiconductor structure 1000. The method of manufacturing the semiconductor structure 1100 further includes forming the insulating layer I5 to cover the surface S3 of the underlayer 1020 before forming the ferroelectric material layer 1030 to cover the surface S3 of the underlayer 1020. In some embodiments, the semiconductor structure 1100 is a MFIM structure. In some embodiments, the insulating layer I5 may include the material of the insulating layer I1 or the insulating layer I2 mentioned previously, so details will not be described again. Since the underlayer 1020 has smaller roughness, the insulating layer I5 and the ferroelectric material layer 1030 can both have good uniformity and flatness, and the ferroelectric material layer 1030 can have good crystallinity and less oxygen vacancies.

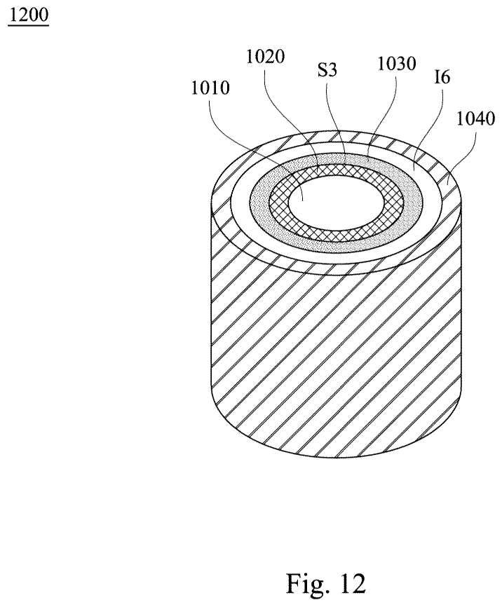

As shown in FIG. 12, a semiconductor structure 1200 further includes an insulating layer I6 disposed between the ferroelectric material layer 1030 and the conductive layer 1040. The semiconductor structure 1200 may be manufactured with reference to the method of manufacturing the semiconductor structure 1000. The method of manufacturing the semiconductor structure 1200 further includes forming the insulating layer I6 to cover the ferroelectric material layer 1030 before forming the conductive layer 1040 to cover the ferroelectric material layer 1030. In some embodiments, the semiconductor structure 1200 is a MIFM structure. In some embodiments, the insulating layer I6 may include the material of the insulating layer I1 or the insulating layer I2 mentioned previously, so details will not be described again.

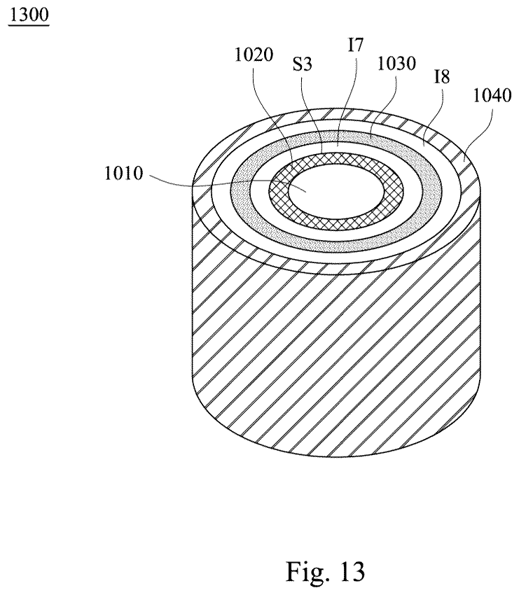

As shown in FIG. 13, the semiconductor structure 1300 further includes a first insulating layer I7 and a second insulating layer I8. The first insulating layer I7 is disposed between the underlayer 1020 and the ferroelectric material layer 1030, and the second insulating layer I8 is disposed between the ferroelectric material layer 1030 and the conductive layer 1040. The semiconductor structure 1300 may be manufactured with reference to the method of manufacturing the semiconductor structure 1000. The method of manufacturing the semiconductor structure 1300 further includes forming the first insulating layer I7 to cover the surface S3 of the underlayer 1020 before forming the ferroelectric material layer 1030 to cover the surface S3 of the underlayer 1020; and forming the second insulating layer I8 to cover the ferroelectric material layer 1030 before forming the conductive layer 1040 to cover the ferroelectric material layer 1030. In some embodiments, the semiconductor structure 1300 is a MIFIM structure. In some embodiments, the first insulating layer I7 or the second insulating layer I8 may include the material of the insulating layer I1 or the insulating layer I2 mentioned previously, so details will not be described again. Since the underlayer 1020 has smaller roughness, both the first insulating layer I7 and the ferroelectric material layer 1030 can have good uniformity and flatness, and the ferroelectric material layer 1030 can have good crystallinity and less oxygen vacancies.

The following describes the features of the present disclosure more specifically with reference to Experimental Examples 1 to 3. Although the following experimental examples are described, the materials, their amounts and ratios, processing details, processing procedures, etc., may be appropriately varied without exceeding the scope of the present disclosure. Accordingly, the present disclosure should not be interpreted restrictively by the experimental examples described below.

### Experimental Example 1: Analysis of Crystallinity of HZO in Semiconductor Structures

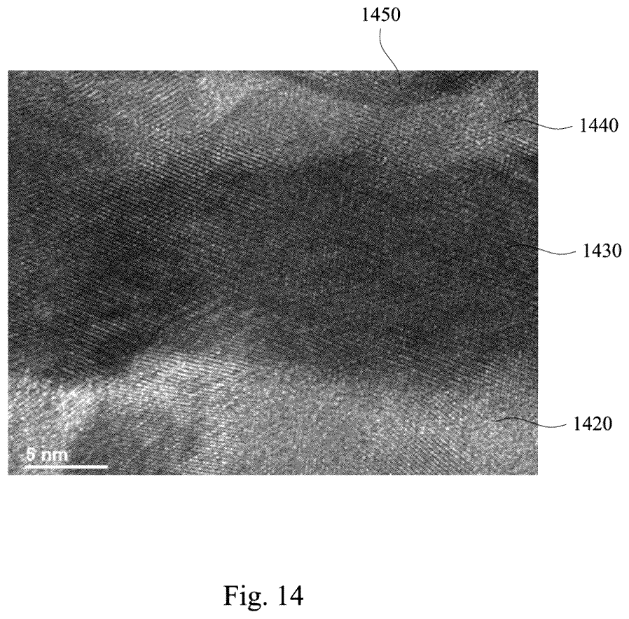

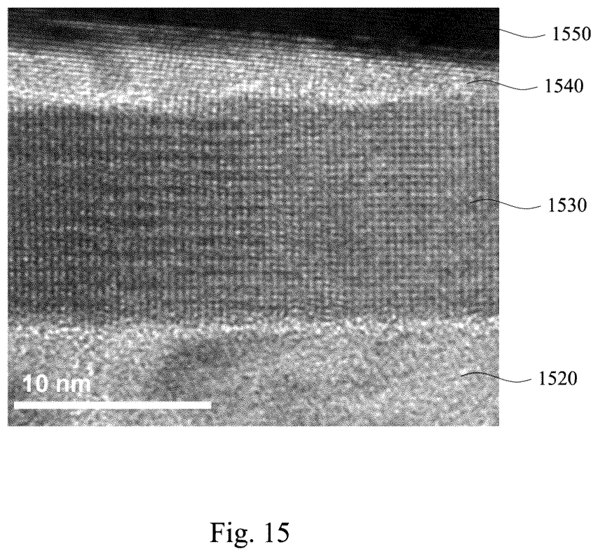

FIG. 14 is a TEM image of a semiconductor structure of Comparative Example 1 according to the present disclosure, in which the semiconductor structure includes a titanium nitride layer 1420, a hafnium zirconium oxide layer 1430, a titanium nitride layer 1440, and a platinum layer 1450. Before forming the hafnium zirconium oxide layer 1430 to cover the titanium nitride layer 1420, the upper surface of the titanium nitride layer 1420 was not planarized by the CMP process. According to AFM, it could be seen that the upper surface of the titanium nitride layer 1420 had a root mean square roughness of 5.4 nm. The formation method of the hafnium zirconium oxide layer 1430 included the following operations. A hafnium zirconium oxide layer was formed by plasma-assisted atomic layer deposition at 250° C., and post metallization annealing (PMA) was performed at 450° C. in an atmosphere containing 90 vol % N₂ and 10 vol % H₂ to crystallize the hafnium zirconium oxide layer to form the hafnium zirconium oxide layer 1430. As shown in FIG. 14, the upper and lower surfaces of the hafnium zirconium oxide layer 1430 formed on the titanium nitride layer 1420 are rough and uneven. FIG. 15 is a TEM image of a semiconductor structure according to Example 1 of the present disclosure, in which the semiconductor structure includes a titanium nitride layer 1520, a hafnium zirconium oxide layer 1530, a titanium nitride layer 1540, and a platinum layer 1550. The titanium nitride layer 1520 has a thickness of 43 nm, and the hafnium zirconium oxide layer 1530 has a thickness of 11 nm. The platinum layer 1550 can prevent oxidation of the titanium nitride layer 1540. For the formation method of the hafnium zirconium oxide layer 1530, please refer to the aforementioned formation method of the hafnium zirconium oxide layer 1430. Before forming the hafnium zirconium oxide layer 1530 to cover the titanium nitride layer 1520, the upper surface of the titanium nitride layer 1520 was planarized by the CMP process, in which the polishing slurry was water. After the CMP process, according to AFM, it could be seen that the upper surface of the titanium nitride layer 1520 had a root mean square roughness of 0.3 nm. The hafnium zirconium oxide layer 1530 was formed by plasma-assisted atomic layer deposition at 250° C. Therefore, as shown in FIG. 15, the upper and lower surfaces of the hafnium zirconium oxide layer 1530 formed on the titanium nitride layer 1520 are substantially flat. Please refer to FIG. 14 and FIG. 15 at the same time. The crystallinity of the hafnium zirconium oxide layer 1530 is better than the crystallinity of the hafnium zirconium oxide layer 1430. Therefore, it can be known that if a bias voltage is applied to the semiconductor structure of FIG. 15, the hafnium zirconium oxide layer 1530 can have less oxygen vacancies, thereby having higher remnant polarization, breakdown voltage, and endurance. The hafnium zirconium oxide layer 1530 can have a breakdown field (E_{BD}) of 4.5 MV/cm.

### Experimental Example 2: Measurement of Breakdown Voltage of Semiconductor Structures

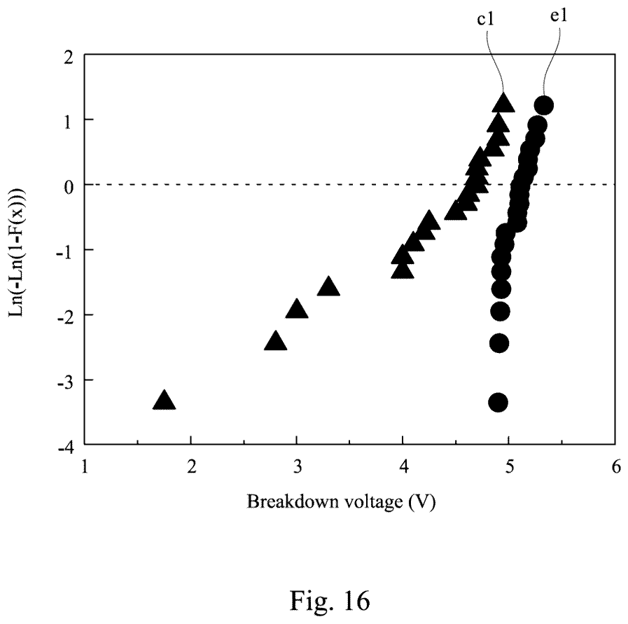

FIG. 16 is a Weibull plot of the breakdown voltages of Example 1 and Comparative Example 1 of the present disclosure. The Weibull plot shows a continuous probability distribution and can be used to evaluate reliability of a semiconductor structure, in which F(x) is a failure rate function. The vertical axis of FIG. 16 represents the probability that the semiconductor structure is still functional. It can be seen from the data points c1 of the semiconductor structure of Comparative Example 1 that since the upper surface of the titanium nitride layer 1420 shown in FIG. 14 is not planarized by the CMP process, the breakdown voltages of the hafnium zirconium oxide layer 1430 are smaller. It can be seen from the data points e1 of the semiconductor structure of Example 1 that since the upper surface of the titanium nitride layer 1520 shown in FIG. 15 is planarized by the CMP process, the breakdown voltages of the hafnium zirconium oxide layer 1530 are larger.

### Experimental Example 3: Measurement of Endurance of Semiconductor Structures

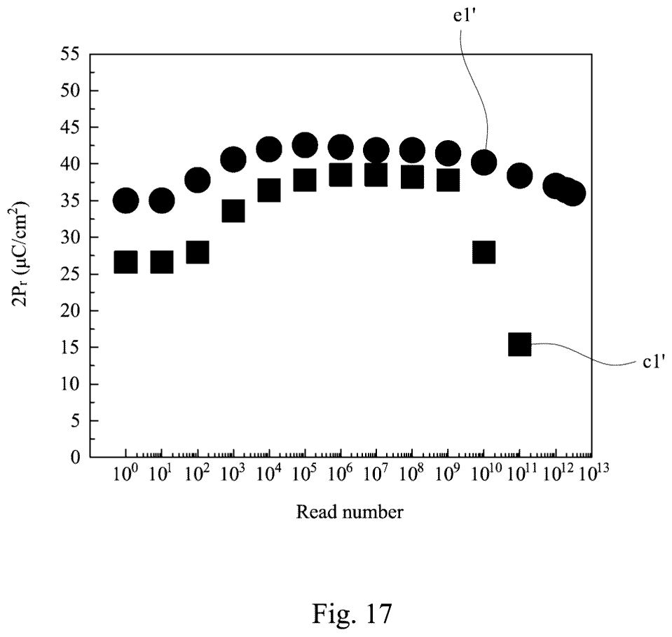

FIG. 17 is a remnant polarization-read number relationship diagram of Example 1 and Comparative Example 1 of the present disclosure. It can be seen from the data points c1′ of the semiconductor structure of Comparative Example 1 that since the upper surface of the titanium nitride layer 1420 is not planarized by the CMP process, the remnant polarization (2Pᵣ) of the hafnium zirconium oxide layer 1430 corresponding to each read number is smaller. Moreover, as the read number increases, the performance of the remnant polarization (2Pᵣ) of the hafnium zirconium oxide layer 1430 becomes worse. Please refer to FIG. 6, FIG. 14, and FIG. 17 at the same time. It can be known that the hafnium zirconium oxide layer 1430 in Comparative Example 1 of FIG. 14 has more oxygen vacancies, so the hafnium zirconium oxide layer 1430 is easily affected by the dipole pinning effect, and thus has lower remnant polarization and poorer endurance.

Please continue to refer to FIG. 17. It can be seen from the data points e1′ of the semiconductor structure of Example 1 that since the upper surface of the titanium nitride layer 1520 is planarized by the CMP process, the remnant polarization (2Pᵣ) of the hafnium zirconium oxide layer 1530 is larger. Moreover, as the read number increases, the remnant polarization (2Pᵣ) of the hafnium zirconium oxide layer 1530 hardly decreases, which means that the semiconductor structure of Example 1 has better endurance. When the read number reaches 3E12, the semiconductor structure of Example 1 still has high remnant polarization. Please refer to FIG. 5, FIG. 15, and FIG. 17 at the same time. It can be known that the hafnium zirconium oxide layer 1530 in Example 1 of FIG. 15 has fewer oxygen vacancies, so the hafnium zirconium oxide layer 1530 is less susceptible to the dipole pinning effect, and thus has higher remnant polarization.

Experimental Example 3 provides a semiconductor structure of Example 2. For its structure and formation method, please refer to the embodiment of the semiconductor structure in FIG. 15. The HZO layer of the semiconductor structure of Example 2 has a thickness of 10 nm, and the TiN layer below the HZO layer has a thickness of 3 nm. The HZO layer of Example 2 can have a remnant polarization (2Pᵣ) of up to 62 μC/cm² and a breakdown field (EBD) of 4.8 MV/cm. After the read number of the semiconductor structure is 4E12, the semiconductor structure of Example 2 can still have a remnant polarization (2Pᵣ) as high as 56 μC/cm².

In summary, the present disclosure provides a semiconductor structure and a manufacturing method thereof. The ferroelectric material layer of the semiconductor structure of the present disclosure has good uniformity, good flatness, good crystallinity, and less oxygen vacancies. Therefore, the semiconductor structure of the present disclosure can have good electrical performance and reliability, such as high remnant polarization, high breakdown voltage, and high endurance.

Although the present disclosure has been described in considerable detail with reference to certain embodiments, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover the modifications and variations of the present disclosure falling within the scope of the appended claims.

What is claimed is:

1. A semiconductor structure, comprising:
a semiconductor substrate;
an underlayer covering the semiconductor substrate;
a ferroelectric material layer covering the underlayer, wherein the underlayer has a surface facing the ferroelectric material layer, and the surface has a root mean square roughness of less than 1 nm; and
a conductive layer covering the ferroelectric material layer.

2. The semiconductor structure of claim 1, further comprising an insulating layer disposed between the underlayer and the ferroelectric material layer.

3. The semiconductor structure of claim 1, further comprising an insulating layer disposed between the ferroelectric material layer and the conductive layer.

4. The semiconductor structure of claim 1, further comprising a first insulating layer and a second insulating layer, wherein the first insulating layer is disposed between the underlayer and the ferroelectric material layer, and the second insulating layer is disposed between the ferroelectric material layer and the conductive layer.

5. The semiconductor structure of claim 1, wherein the semiconductor substrate is columnar, the underlayer surrounds the semiconductor substrate, the ferroelectric material layer surrounds the underlayer, and the conductive layer surrounds the ferroelectric material layer.

6. The semiconductor structure of claim 5, further comprising an insulating layer disposed between the underlayer and the ferroelectric material layer.

7. The semiconductor structure of claim 5, further comprising an insulating layer disposed between the ferroelectric material layer and the conductive layer.

8. The semiconductor structure of claim 5, further comprising a first insulating layer and a second insulating layer, wherein the first insulating layer is disposed between the underlayer and the ferroelectric material layer, and the second insulating layer is disposed between the ferroelectric material layer and the conductive layer.

9. The semiconductor structure of claim 1, wherein the underlayer has a thickness of 0.5 nm to 50 nm.

10. The semiconductor structure of claim 1, wherein the underlayer comprises titanium, titanium nitride, titanium aluminum alloy, titanium aluminum nitride, tungsten, tungsten nitride, tantalum, tantalum nitride, ruthenium, ruthenium dioxide, molybdenum, molybdenum dioxide, molybdenum trioxide, silicon, germanium, silicon germanium, or combinations thereof.

11. A method of manufacturing a semiconductor structure, comprising:
forming an underlayer to cover a semiconductor substrate;
treating a surface of the underlayer to lower a roughness of the surface;
forming a ferroelectric material layer to cover the surface of the underlayer; and
forming a conductive layer to cover the ferroelectric material layer.

12. The method of claim 11, wherein treating the surface of the underlayer to lower the roughness of the surface comprises: planarizing the surface by a chemical mechanical polishing process.

13. The method of claim 12, wherein a polishing slurry of the chemical mechanical polishing process comprises water.

14. The method of claim 11, further comprising: forming an insulating layer to cover the surface of the underlayer before forming the ferroelectric material layer to cover the surface of the underlayer.

15. The method of claim 11, further comprising: forming an insulating layer to cover the ferroelectric material layer before forming the conductive layer to cover the ferroelectric material layer.

16. The method of claim 11, further comprising:
before forming the ferroelectric material layer to cover the surface of the underlayer, forming a first insulating layer to cover the surface of the underlayer; and
before forming the conductive layer to cover the ferroelectric material layer, forming a second insulating layer to cover the ferroelectric material layer.

17. The method of claim 11, wherein the semiconductor substrate is columnar, and forming the underlayer to cover the semiconductor substrate comprises: forming the underlayer to surround a sidewall of the semiconductor substrate.

18. The method of claim 17, further comprising: forming an insulating layer to cover the surface of the underlayer before forming the ferroelectric material layer to cover the surface of the underlayer.

19. The method of claim 17, further comprising: forming an insulating layer to cover the ferroelectric material layer before forming the conductive layer to cover the ferroelectric material layer.

20. The method of claim 11, wherein after treating the surface of the underlayer to lower the roughness of the surface, the surface has a root mean square roughness of less than 1 nm.
